(19) United States
(12) Patent Application Publication
(10) Pub. No.: US 2007/0194210 A1
(43) Pub. Date: Aug. 23, 2007

(54) Light emitting apparatus and control method thereof

(75) Inventors: Sang-hoon Lee, Nam-gu (KR); Jeong-il Kang, Yongin-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 11/657,063

(22) Filed: Jan. 24, 2007

(30) Foreign Application Priority Data
Feb. 21, 2006 (KR) 10-2006-0016901

(51) Int. Cl. H01J 40/14; G01J 1/44; H03F 3/08

(52) U.S. Cl. 250/214 R

(57) ABSTRACT

A light emitting apparatus and control method are provided. The light emitting apparatus includes a light emitting part; a power supply which applies a voltage to the light emitting part; a switch which is connected in series with the light emitting part; and a controller which controls the power supply to maintain a current applied to the switch, to apply a first voltage level to the light emitting part for a reserve time when the light emitting part is initially driven, and to apply a second voltage level to the light emitting part after the reserve time elapses. The light emitting apparatus and control method increase the temperature of a light emitting part by supplying power to the light emitting part for a reserve time before the light emitting part is driven normally at an initial stage of driving the light emitting part.

### CROSS-REFERENCE TO RELATED APPLICATIONS

This application claims priority from Korean Patent Application No. 2006-0016901, filed on Feb. 21, 2006 in the Korean Intellectual Property Office, the disclosure of which is incorporated herein by reference.

### BACKGROUND OF THE INVENTION

1. Field of the Invention

Apparatuses and methods consistent with the present invention relate to a light emitting apparatus and a control method thereof, and more particularly, to a light emitting apparatus which is capable of improving light-emission characteristics by controlling the sequence of driving a plurality of light emitting parts at an initial stage of driving the light emitting elements, and a control method thereof.

2. Description of the Related Art

Cathode ray tubes (CRTs) and flat panel displays (FPDs) are used as display apparatuses. A flat panel display mainly uses a liquid crystal display (LCD) panel or a plasma display panel (PDP). In addition, other types of display apparatuses, such as organic electroluminescence (EL) and digital lighting processing (DLP), are being actively developed.

A display apparatus employing an LCD or DLP uses light emitting elements, such as light emitting diodes (LEDs), which are point light sources. LEDs have a high brightness and good color reproduction, and therefore are used as light sources for a backlight unit. In order to improve the quality of the image to be displayed, a light emitting element driven by current, such as an LED, requires a driving device that minimizes ripple components of an output current and has a fast response characteristic. To this end, a linear-type current source apparatus is used.

In a light emitting apparatus having a light emitting part such as an LED, a forward voltage drop (V_{L}) of the light emitting part depends on its temperature. When the temperature of the light emitting part is low, such as at an initial stage of driving of the light emitting part, the forward voltage drop produced in the light emitting part increases, and then is stabilized as it gradually decreases with time during light emission. If an output voltage of the light emitting part is increased to meet the level of the initial increasing forward voltage drop of the light emitting part, an output voltage range of a voltage source of the light emitting apparatus increases, which may lead to difficulty in designing the apparatus, as well as an increase in production costs of the apparatus. On the contrary, if the output voltage range of the voltage source is set to be narrow in a normal state, a voltage higher than a voltage in the normal state is produced as the output voltage when adjusting a voltage. Then, a voltage decreased by an amount applied to the light emitting part when the light emitting part is sufficiently stabilized is applied to other ambient elements, which may lead to an increase in other ambient elements, and a decrease in the overall efficiency of the light emitting apparatus.

### SUMMARY OF THE INVENTION

Exemplary embodiments of the present invention overcome the above disadvantages and other disadvantages not described above. Also, the present invention is not required to overcome the disadvantages described above, and an exemplary embodiment of the present invention may not overcome any of the problems described above.

The present invention provides a light emitting apparatus which is capable of increasing the temperature of a light emitting part by supplying power to the light emitting part for a reserve time before the light emitting part is driven normally at an initial stage of driving the light emitting part, and a control method thereof.

According to an aspect of the present invention, there is provided a light emitting apparatus comprising a light emitting part; a power supply which applies a voltage to the light emitting part; a switch which is connected in series with the light emitting part; and a controller which controls the power supply to maintain a current applied to the switch, to apply a first voltage level to the light emitting part for a reserve time when the light emitting part is initially driven, and to apply a second voltage level to the light emitting part after the reserve time elapses.

According to an aspect of the invention, the light emitting apparatus further comprises a temperature sensor which senses a temperature of the light emitting part, wherein the controller controls the power supply to apply the first voltage level to the light emitting part until the temperature of the light emitting part reaches a reference temperature when the light emitting part is initially driven.

According to an aspect of the invention, when the light emitting part is initially driven, the controller controls the power supply to apply the first voltage level to the light emitting part for the reserve time, to adjust the first voltage level to the second voltage level for a voltage adjustment time, and to apply the second voltage level to the light emitting part after the voltage adjustment time.

According to an aspect of the invention, when the light emitting part is initially driven, the controller controls the switch so that the reserve time starts and current is applied to the light emitting part after a voltage stabilization time, during which a voltage which is initially supplied from the power supply is stabilized.

According to an aspect of the invention, the controller detects a current flowing through the light emitting part, and controls the switch so that the detected current is within a range.

According to an aspect of the invention, the controller comprises a current sensing resistor which is connected in series with the light emitting part, and wherein the controller detects the current flowing through the light emitting part based on a voltage applied to the current sensing resistor.

According to an aspect of the invention, the controller comprises a switching controlling part which controls the switch based on the current flowing through the light emitting part.

According to an aspect of the invention, the first voltage level is higher than the second voltage level.

According to an aspect of the invention, the light emitting part comprises a light emitting diode.

According to an aspect of the invention, the light emitting apparatus further comprises a display which receives light emitted from the light emitting part, and displaying an image.

According to another aspect of the present invention, there is provided a light emitting apparatus comprising a plurality of light emitting parts; a power supply which applies a voltage to the light emitting parts; a switch which is connected in series with the light emitting parts; and a controller which controls the power supply to maintain a current applied to the switch, to adjust a voltage applied to the light emitting parts for a reserve time until the voltage reaches a first voltage level when the plurality of light emitting parts are initially driven, to apply the first voltage level to the light emitting parts, and to apply a second voltage level to the light emitting parts after the reserve time elapses.

According to an aspect of the invention, the light emitting apparatus further comprises a temperature sensor which senses a temperature of the light emitting parts, wherein the controller controls the power supply to apply the first voltage level to the light emitting parts until the temperature of the light emitting parts reaches a reference temperature when the light emitting parts are initially driven.

According to another aspect of the present invention, there is provided a method of controlling a light emitting apparatus comprising a plurality of light emitting parts, comprising providing a switch which is connected in series with the light emitting parts; initially applying a voltage to the light emitting parts; applying a first voltage level to the light emitting parts for a reserve time; applying a second voltage level to the light emitting parts after the reserve time elapses; and controlling a current applied to the switch so that the current is maintained.

According to an aspect of the invention, the method further comprises sensing a temperature of the light emitting parts, wherein applying the first voltage level to the light emitting parts continues until the temperature of the light emitting parts reaches a reference temperature.

According to an aspect of the invention, applying the first voltage level to the light emitting parts begins after a voltage stabilization time during which an initially supplied voltage is stabilized, and wherein controlling the current applied to the switch to be constantly maintained comprises applying current to the light emitting parts after the voltage stabilization time.

### BRIEF DESCRIPTION OF THE DRAWINGS

The above and other aspects of the present invention will become apparent and more readily appreciated from the following description of exemplary embodiments, taken in conjunction with the accompanying drawings of which:

FIG. 1 is a control block diagram of a light emitting apparatus according to an exemplary embodiment of the present invention;

FIGS. 2A, 2B, and 3 are diagrams showing the voltage level applied from a power supply to a light emitting part, and the magnitude of current applied to the light emitting part, according to an exemplary embodiment of the present invention; and

FIGS. 4A and 4B are control flow diagrams illustrating the operation of a light emitting apparatus according to exemplary embodiments of the present invention.

### DETAILED DESCRIPTION OF EXEMPLARY EMBODIMENTS OF THE INVENTION

Reference will now be made in detail to exemplary embodiments of the present invention, examples of which are illustrated in the accompanying drawings.

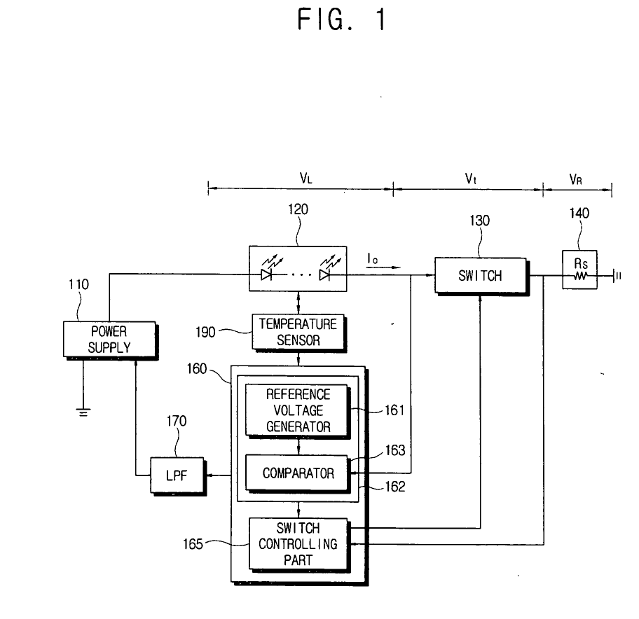

Referring to FIG. 1, a light emitting apparatus according to an exemplary embodiment of the present invention includes a light emitting part 120 which emits light, a power supply 110, a switch 130, and a controller 160 which controls these components. The light emitting apparatus may further include at least one of a temperature sensor 190 which senses the temperature of the light emitting part 120, a low pass filter (LPF) 170, and a current sensing resistor 140.

The power supply 110, which is a power source which supplies a constant voltage to the light emitting part 120, outputs variable power to the light emitting part 120 in order to maintain a constant driving voltage applied to the switch 130 by the controller 160. The power supply 110 may vary power from a level higher than a maximal voltage, which may be applied to the light emitting part 120, to a level lower than a minimal voltage, which may be applied to the light emitting part 120. In other words, the power supply 110 may vary the power from a sufficiently high voltage to an optimal voltage, since a forward voltage drop V_{L} of the light emitting part 120 gradually decreases until the forward voltage drop V_{L} is stabilized. The power supply 110 may comprise a variable DC voltage source.

The light emitting part 120 emits light on a screen (not shown) on which an image is displayed. In an exemplary embodiment, the light emitting part 120 may include light emitting diodes (LEDs). The LEDs include a red LED for emitting red light, a green LED for emitting green light, and a blue LED for emitting blue light. The LEDs may further include other various LEDs, such as a cyan LED for emitting cyan light, a yellow LED for emitting yellow light, a magenta LED for emitting magenta light, and a white LED for emitting white light.

As shown in FIG. 1, the light emitting part 120 includes a plurality of LEDs connected in series. Alternatively, the light emitting apparatus may include a plurality of light emitting parts 120 which are connected in series or in parallel, or to a separate circuit. Also, the light emitting part 120 may include one or more LEDs.

The switch 130, which is connected in series with the light emitting part 120, is a constant current source that generates a constant current required for the light emitting apparatus using the constant voltage supplied from the power supply 110. The switch 130 may include one of a field effect transistor (FET) and a bipolar junction transistor (BJT). Since current flowing between a collector and an emitter of the BJT or between a drain and a source of the FET can be controlled by adjusting a signal applied to a base of the BJT or a gate of the FET, a circuit including the FET and the BJT may control the power supplied to the light emitting part 120 of the light emitting apparatus at a very high switching speed, with high precision and without noise. For example, for the FET, current flowing between the drain and the source of the FET in a saturated region has a tendency to remain at a certain value, irrespective of a voltage applied between the drain and the source. Accordingly, a constant current can be produced.

The current sensing resistor 140 senses the magnitude of current applied to the light emitting part 120. In this exemplary embodiment, the current sensing resistor 140 is connected between the switch 130 and a ground, and senses the magnitude of current flowing through the switch 130. Since a resistance of the current sensing resistor 140 is very small, a voltage V_{R} across the current sensing resistor 140 may be neglected. Since the light emitting part 120, the switch 130, and the current sensing resistor 140 are connected in series, the magnitude of current flowing through each of these components is equal.

The current sensing resistor 140 comprises resistors to detect the current flowing through the light emitting part 120 and the switch 130. Alternatively, a current detecting circuit including a Hall sensor may be used to detect the current.

In an exemplary embodiment, the connection order of the light emitting part 120, the switch 130, and the current sensing resistor 140, may be changed.

The LPF 170 converts a control signal received from the controller 160 into a signal readable by the power supply 110. The controller 160 includes a digital signal processor (DSP) and a field programmable gate array (FPGA) and the LPF 170 may extract a direct current component by filtering a pulse width modulation (PWM) signal output from the controller 160.

In an exemplary embodiment, instead of the LPF 170, a digital-analog converter (DAC) may be used to convert a digital signal into an analog signal, and an analog to digital converter (ADC) may be used to convert a signal input to the controller 160 into a digital signal. In addition, the controller 160 may be designed to be an analog circuit, instead of a digital circuit.

The temperature sensor 190 senses the temperature of the light emitting part 120, and transmits the sensed temperature to the controller 160.

The controller 160 includes a main controlling part 162 and a switching controlling part 165.

The switching controlling part 165 detects the current flowing through the switch 130, and controls the switch 130 so that the magnitude of the current detected based on a reference current Ir of a preset range input from the controller 160 is within a predetermined range. In an exemplary embodiment, the switching controlling part 165 detects the voltage level across the current sensing resistor 140. Since the resistance of the current sensing resistor 140 is fixed at Rs, the switching controlling part 165 can calculate the magnitude of current applied to the switch 130 according to the formula V=IR.

As long as the voltage supplied from the power supply 110 is maintained to be higher than the overall forward voltage drop V_{L} of the light emitting part 120, the switching controlling part 165 may control the detected current to be within the predetermined range, irrespective of a characteristic of the switch 130, the supplied power, and the forward voltage drop V_{L} of the light emitting part 120.

The main controlling part 162 includes a reference voltage generator 161 and a comparator 163, and controls the power supply 110 so that a voltage across the switch 130 is constantly maintained in response to a variation of the voltage across the light emitting part 120.

In general, the voltage Vt across the switch 130 depends on the voltage V_{L} across the light emitting part 120. The voltage Vt across the switch 130 corresponds to a subtraction of the voltage V_{L} across the light emitting part 120 from a voltage of supplied driving power. As the voltage Vt increases, power consumption in the switch 130 increases.

Accordingly, even though the environment may vary, or the light emitting part 120 may change, the power supplied to the light emitting part 120 can be varied to make the voltage Vt across the switch 130 constant. In addition, the voltage Vt across the switch 130 may be set to a voltage level for minimization of power consumption.

The main controlling part 162 controls the power supply 110 to supply a first voltage level to the light emitting part 120 for a preset reserve time at an initial stage of driving of a plurality of light emitting parts 120. After the reserve time elapses, the main controlling part 162 can control the power supply 110 to supply a second voltage level to the light emitting part 120. The first voltage level is supplied to the light emitting part 120 for the preset reserve time to prevent errors or power consumption due to low temperature of the light emitting part 120 at an initial stage of supply of power to the light emitting part 120.

In an exemplary embodiment, the main controlling part 162 stores the preset reserve time. The main controlling part 162 can control the power supply 110 to supply the first voltage level to the light emitting part 120 for the stored preset reserve time at the initial stage of driving of the light emitting part 120.

In another exemplary embodiment, the main controlling part 162 may control the power supply 110 to supply the first voltage level to the light emitting part 120 until the temperature of the light emitting part 120 reaches a reference temperature at the initial stage of driving of the light emitting part 120. In this case, the preset reserve time ends when the temperature of the light emitting part 120 reaches the reference temperature.

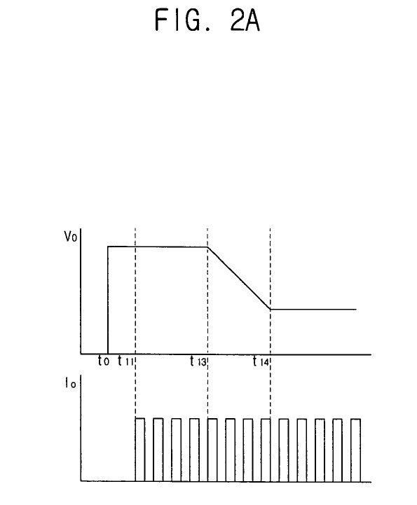

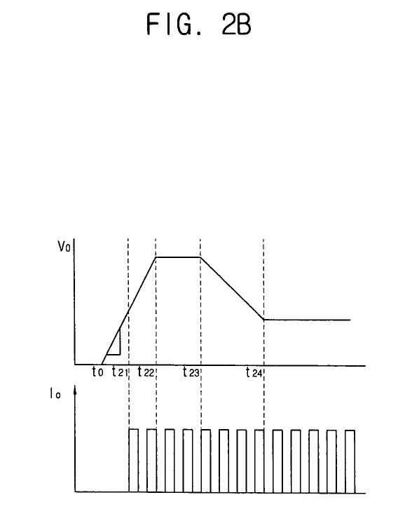

FIGS. 2A and 2B are diagrams showing the level of a driving voltage applied from the power supply 110 to the light emitting part 120, and the magnitude of current applied to the light emitting part 120, according to an exemplary embodiment of the present invention.

Referring to FIG. 2A, the main controlling part 162 controls the power supply 110 to output the first voltage level to the light emitting part 120 at an initial stage (t0) of driving of the light emitting part 120, and then causes the first voltage level to be applied to the light emitting part 120 from a point t11 to a point t 13 after the first voltage level is stably outputted from the power supply 110. The time from the point t11 to the point t13 corresponds to the preset reserve time. Thus, the temperature of the light emitting part 120, which was cold at an initial stage, gradually increases. Accordingly, the voltage V_{L} applied to the light emitting part 120 becomes sufficiently lowered and stabilized.

The reserve time may be adjusted based on the kind of the light emitting part 120, such as a characteristic of a light emitting diode. After the reserve time elapses, the controller 160 sets a driving voltage to be used to drive the light emitting part 120. The driving voltage corresponds to the above-mentioned second voltage level. The controller 160 adjusts the level of the driving voltage output from the power supply 110 from the point t13 to a point t14 so that the driving voltage applied to the light emitting part 120 becomes the second voltage level. After the point t14, the light emitting part 120 operates with the second voltage level appropriate for driving the light emitting part 120.

Current may be applied to the light emitting part 120 after the point t11 when the driving voltage is stabilized. The magnitude of current flowing through the light emitting part 120 is adjusted according to the switching of the switch 130, and the magnitude of current Io is adjusted according to an on/off operation of the switch 130.

The light emitting apparatus of exemplary embodiments of the present invention may include a cooling fan (not shown). The cooling fan may be used to maintain the temperature of various components in the light emitting apparatus below a fixed level. The controller 160 may control the cooling fan to be driven after the reserve time elapses.

FIG. 2B shows an operation principle of the light emitting apparatus that is similar to the principle illustrated in FIG. 2A, except that the controller 160 can control the power supply 110 so that the driving voltage output from the power supply 110 gradually increases at the initial stage of driving of the light emitting part 120. To gradually increase the driving voltage to reach the first voltage level, the driving voltage may be adjusted by increasing a pulse width of the PWM signal to generate a reference voltage for voltage adjustment in the controller 160, or the driving voltage may be adjusted in an analog fashion using a soft start function.

A start point of the reserve time may be set to be a point t21 when the driving voltage reaches a preset reference voltage, or a point t22 when the driving voltage reaches the first voltage level. In addition, as can be seen from FIG. 2B, the reserve time ends at a point t23, the driving voltage is adjusted to the second voltage level as a normal driving voltage up to a point t24, and the light emitting part 120 is driven normally after the point t24.

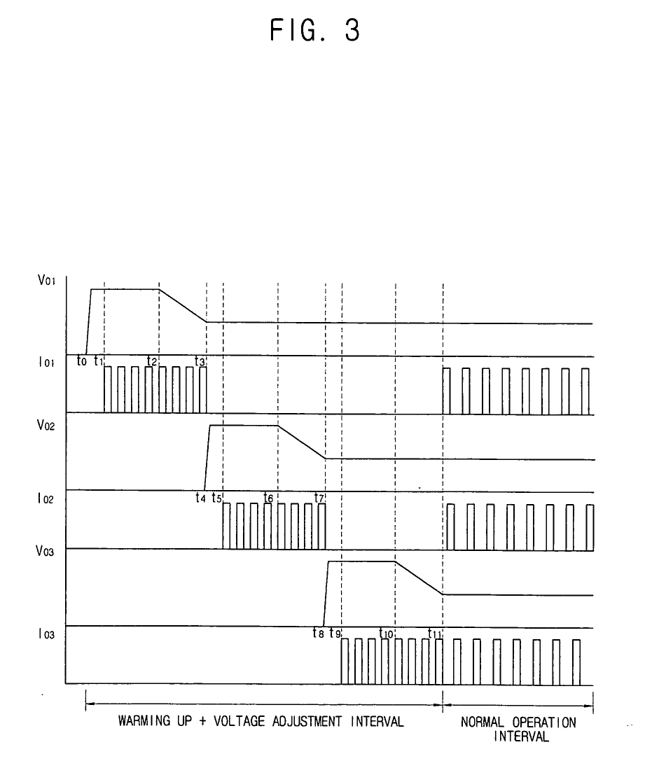

FIG. 3 is a diagram showing one example of a driving state of each of three light emitting parts 120 included in the light emitting apparatus according to an exemplary embodiment of the present invention. The three light emitting parts 120 may include a light emitting part having a red LED, a light emitting part having a green LED, and a light emitting part having a blue LED.

The light emitting parts 120 shown in FIG. 3 emit light sequentially in a reserve mode in which a voltage is set. Switches 130 for adjusting the current applied to the light emitting parts 120 are not simultaneously switched on, and accordingly, the light emitting parts 120 do not emit light simultaneously. In addition, the power supply 110 does not supply power to the light emitting parts 120 simultaneously at the initial driving stage.

Alternatively, the light emitting parts 120 may receive power from the power supply 110 simultaneously at a point t0, or the controller 160 may control more than one light emitting part 120 so that the reserve times end simultaneously. In addition, the switches 130 for adjusting the current flowing through the light emitting parts may be designed to be simultaneously switched on. When the light emitting parts 120 are driven, levels V₀₁, V₀₂, and V₀₃ of the driving voltage applied to the light emitting parts 120 may be equally or differently set in consideration of the voltage V1 applied to the light emitting parts 120.

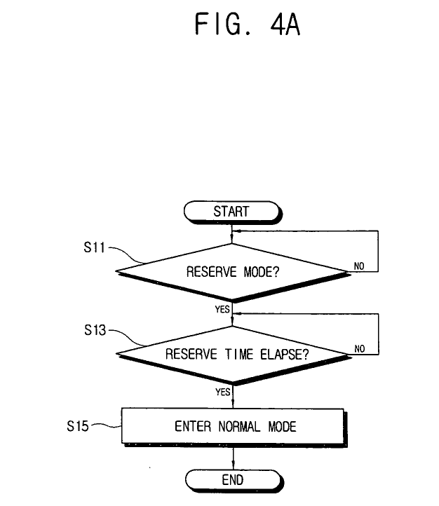

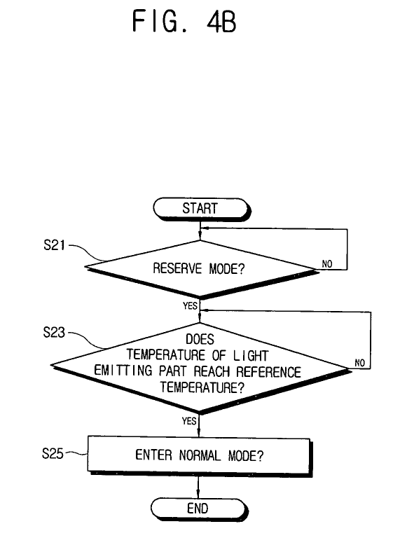

FIGS. 4A and 4B are control flow diagrams illustrating the operation of the light emitting apparatus according to exemplary embodiments of the present invention.

As described above, the light emitting apparatus of the present invention includes the switch 130, which is connected in series with the light emitting part 120 for adjusting the magnitude of current applied to the light emitting part 120.

According to an exemplary embodiment of the present invention, as shown in FIG. 4A, after an initial driving voltage is applied to the light emitting part 120, the light emitting apparatus starts a reserve time at operation S11. A driving mode of the light emitting apparatus during the reserve time is referred to as a reserve mode.

When the initial driving voltage is applied to the light emitting part 120, a voltage applied from the power supply 110 to the light emitting part 120 is stabilized after a voltage stabilization time elapses. After the voltage stabilization time elapses, the switching controlling part 165 may sense the magnitude of current applied to the switch 130, and control the switching of the switch 130 so that the magnitude of current is constantly maintained. In, addition, after the voltage stabilization time elapses, the reserve mode begins. The reserve time begins when the first voltage level may be applied to the light emitting part 120.

The controller 160 may determine that the reserve mode starts from a point when the initial driving voltage is applied to the light emitting part 120, without determining the voltage stabilization time separately. In addition, the first voltage level may be applied to the light emitting part 120 before or after the reserve time. According to an exemplary embodiment of the present invention, the reserve time is a preset time.

If the controller 160 determines at operation S13 that the reserve time elapses, the controller 160 enters a normal mode, and controls the power supply 110 to apply the second voltage level to the light emitting part 120 at operation S15. The normal mode may include a voltage adjustment interval for adjustment of the level of the driving voltage applied to the light emitting part 120. After the reserve time elapses, the light emitting part 120 of the light emitting apparatus is driven normally after the voltage adjustment interval in which the first voltage level is adjusted to the second voltage level elapses.

According to an exemplary embodiment of the present invention, as shown in FIG. 4B, after an initial driving voltage is applied to the light emitting part 120, the light emitting apparatus starts a reserve time at operation S21. A driving mode of the light emitting apparatus during the reserve time is referred to as a reserve mode.

After entering the reserve mode, the temperature sensor 190 senses the temperature of the light emitting part 120, and the controller 160 determines whether or not the sensed temperature of the light emitting part 120 has reached a reference temperature. The controller 160 may determine that the reserve time has elapsed at a point when the temperature of the light emitting part reaches the reference temperature.

If the controller 160 determines at operation S23 that the reserve time has elapsed when the temperature of the light emitting part 120 reaches the reference temperature, the controller 160 enters the normal mode at operation S25. The light emitting apparatus enters the voltage adjustment interval for adjusting the level of the driving voltage applied to the light emitting part 120. In addition, the controller 160 may control the power supply 110 so that the driving voltage applied to the light emitting part 120 changes from the first voltage level to the second voltage level, which is the voltage level that is appropriate for the driving of the light emitting part 120. The second voltage level may be lower than the first voltage level.

The light emitting apparatus of exemplary embodiments of the present invention may further include a display for receiving light emitted from the light emitting part 120 and displaying an image. The display may include various panels, such as an LCD panel, a PDP, or a panel on which an image produced by a projection system.

As described above, the light emitting apparatus of the present invention is driven normally after increasing the temperature of the light emitting part 120 at the initial stage of the driving. The temperature of the light emitting part 120 is increased by applying the first voltage level, which is higher than the second voltage level as a normal driving voltage, to the light emitting part 120. Since the light emitting part 120 emits light stably, it is possible to reduce stress of ambient components, which is caused by variations of the driving voltage applied to the light emitting part 120 due to variations of the temperature of the light emitting part 120 at the initial stage of the driving, and reduce power consumption of the light emitting apparatus.

As apparent from the above description, the present invention provides a light emitting apparatus which is capable of increasing a temperature of a light emitting part by applying a voltage to the light emitting part for a reserve time before the light emitting part is driven normally at an initial stage of driving of the light emitting part, and a control method thereof.

Accordingly, the efficiency of various components of the light emitting apparatus can be improved by normally driving the light emitting part after stabilizing the level of the driving voltage applied to the light emitting part, whose temperature increases.

Although a few exemplary embodiments of the present invention have been shown and described, it will be appreciated by those skilled in the art that changes may be made in these embodiments without departing from the principles and spirit of the invention, the scope of which is defined in the appended claims and their legal equivalents.

What is claimed is:

1. A light emitting apparatus comprising:
a light emitting part;
a power supply which applies a voltage to the light emitting part;
a switch which is connected in series with the light emitting part; and
a controller which controls the power supply to maintain a current applied to the switch, to apply a first voltage level to the light emitting part for a reserve time when the light emitting part is initially driven, and to apply a second voltage level to the light emitting part after the reserve time elapses.

2. The light emitting apparatus according to claim 1, further comprising a temperature sensor which senses a temperature of the light emitting part,
wherein the controller controls the power supply to apply the first voltage level to the light emitting part until the temperature of the light emitting part reaches a reference temperature when the light emitting part is initially driven.

3. The light emitting apparatus according to claim 1, wherein when the light emitting part is initially driven, the controller controls the power supply to apply the first voltage level to the light emitting part for the reserve time, to adjust the first voltage level to the second voltage level for a voltage adjustment time, and to apply the second voltage level to the light emitting part after the voltage adjustment time.

4. The light emitting apparatus according to claim 3, wherein the controller controls the switch so that the reserve time starts and current is applied to the light emitting part after a voltage stabilization time during which a voltage which is initially supplied from the power supply is stabilized.

5. The light emitting apparatus according to claim 4, wherein the controller detects a current flowing through the light emitting part, and controls the switch so that the detected current is within a range.

6. The light emitting apparatus according to claim 5, wherein the controller comprises a current sensing resistor which is connected in series with the light emitting part, and
wherein the controller detects the current flowing through the light emitting part based on a voltage applied to the current sensing resistor.

7. The light emitting apparatus according to claim 6, wherein the controller comprises a switching controlling part which controls the switch based on the current flowing through the light emitting part.

8. The light emitting apparatus according to claim 3, wherein the first voltage level is higher than the second voltage level.

9. The light emitting apparatus according to claim 3, wherein the light emitting part comprises a light emitting diode.

10. The light emitting apparatus according to claim 3, further comprising a display which receives light emitted from the light emitting part, and displays an image.

11. The light emitting apparatus according to claim 2, wherein when the light emitting part is initially driven, the controller controls the power supply to apply the first voltage level to the light emitting part for the reserve time, to adjust the first voltage level to the second voltage level for a voltage adjustment time, and to apply the second voltage level to the light emitting part after the voltage adjustment time.

12. The light emitting apparatus according to claim 11, wherein the controller controls the switch so that the reserve time starts and current is applied to the light emitting part after a voltage stabilization time during which a voltage which is initially supplied from the power supply is stabilized.

13. The light emitting apparatus according to claim 12, wherein the controller detects a current flowing through the light emitting part, and controls the switch so that the detected current is within a range.

14. The light emitting apparatus according to claim 13, wherein the controller comprises a current sensing resistor which is connected in series with the light emitting part, and
wherein the controller detects the current flowing through the light emitting part based on a voltage applied to the current sensing resistor.

15. The light emitting apparatus according to claim 14, wherein the controller comprises a switching controlling part which controls the switch based on the current flowing through the light emitting part.

16. The light emitting apparatus according to claim 11, wherein the first voltage level is higher than the second voltage level.

17. The light emitting apparatus according to claim 11, wherein the light emitting part comprises a light emitting diode.

18. The light emitting apparatus according to claim 11, further comprising a display which receives light emitted from the light emitting part, and displays an image.

19. A light emitting apparatus comprising:
a plurality of light emitting parts;
a power supply which applies a voltage to the light emitting parts;
a switch which is connected in series with the light emitting parts; and
a controller which controls the power supply to maintain a current applied to the switch, to adjust a voltage applied to the light emitting parts for a reserve time until the voltage reaches a first voltage level when the plurality of light emitting parts are initially driven, to apply the first voltage level to the light emitting parts, and to apply a second voltage level to the light emitting parts after the reserve time elapses.

20. The light emitting apparatus according to claim 19, further comprising a temperature sensor which senses a temperature of the light emitting parts,
wherein the controller controls the power supply to apply the first voltage level to the light emitting parts until the temperature of the light emitting parts reaches a reference temperature when the light emitting parts are initially driven.

21. A method of controlling a light emitting apparatus comprising a plurality of light emitting parts, comprising:
providing a switch which is connected in series with the light emitting parts;
initially applying a voltage to the light emitting parts;
applying a first voltage level to the light emitting parts for a reserve time;
applying a second voltage level to the light emitting parts after the reserve time elapses; and
controlling a current applied to the switch so that the current is constantly maintained.

22. The method according to claim 21, further comprising sensing a temperature of the light emitting parts,
wherein the applying the first voltage level to the light emitting parts continues until the temperature of the light emitting parts reaches a reference temperature.

23. The method according to claim 22, wherein the applying the first voltage level to the light emitting parts begins after a voltage stabilization time during which an initially supplied voltage is stabilized, and
wherein the controlling the current applied to the switch comprises applying current to the light emitting parts after the voltage stabilization time.
